(19) United States
(12) Patent Application Publication
(10) Pub. No.: US 2025/0285890 A1
(43) Pub. Date: Sep. 11, 2025

(54) SEMICONDUCTOR MANUFACTURING DEVICE AND METHOD OF MANUFACTURING SEMICONDUCTOR DEVICE

(71) Applicant: Kioxia Corporation, Tokyo (JP)

(72) Inventors: Ryo Nishikawa, Yokkaichi Mie (JP); Yosuke Maruyama, Yokkaichi Mie (JP); Shinsuke Kimura, Yokkaichi Mie (JP); Satoshi Nakaoka, Yokkaichi Mie (JP); Hiroyasu Iimori, Nagoya Aichi (JP); Fuyuma Ito, Yokkaichi Mie (JP)

(21) Appl. No.: 18/977,848

(22) Filed: Dec. 11, 2024

(30) Foreign Application Priority Data
Mar. 5, 2024 (JP) 2024-033198

(51) Int. Cl. H01L 21/67; H01L 21/02

(52) U.S. Cl. CPC H01L 21/67253; H01L 21/02019; H01L 21/67086

(57) ABSTRACT

A semiconductor manufacturing device includes a treatment tank in which treatment of a workpiece is performed using a chemical solution containing nitric acid, a pipe connected to the treatment tank and through which nitric oxide (NO) that is generated by the treatment is recovered from the treatment tank, and a sensor configured to detect and output a physical quantity related to an amount of the NO that is recovered through the pipe.

### CROSS-REFERENCE TO RELATED APPLICATIONS

This application is based upon and claims the benefit of priority from Japanese Patent Application No. 2024-033198, filed Mar. 5, 2024, the entire contents of which are incorporated herein by reference.

### FIELD

Embodiments described herein relate generally to a semiconductor manufacturing device and to a method of manufacturing a semiconductor device.

### BACKGROUND

Reaction by-products that are created in semiconductor manufacturing processes are, for example, sometimes discharged and not effectively utilized.

### BRIEF DESCRIPTION OF THE DRAWINGS

FIG. 1 is a block diagram showing a configuration of a semiconductor manufacturing device according to a first embodiment.

FIG. 2 is a cross sectional view of a treatment tank according to the first embodiment.

FIG. 3 is a cross sectional view of a metal film according to the first embodiment.

FIG. 4 is a graph showing a relationship between NO concentration and treatment time according to the first embodiment.

FIG. 5 is a graph showing a relationship between an amount of recess and elapsed time according to the first embodiment.

FIG. 6 is a diagram showing a configuration of a semiconductor manufacturing device according to a second embodiment.

FIG. 7 is a block diagram showing a configuration of a semiconductor manufacturing device according to a third embodiment.

FIG. 8 is a graph showing a relationship between emission intensity and treatment time according to the third embodiment.

FIG. 9 is a graph showing a relationship between nitric acid concentration and treatment time according to a fourth embodiment.

FIG. 10 is a graph showing a relationship between a rate of a regeneration amount of nitric acid and treatment time according to the fourth embodiment.

### DETAILED DESCRIPTION

From the perspective of productivity, there is a need for a method of detecting the end of etching treatment in metal etching using phosphoric, acetic, and nitric acids.

In general, according to one embodiment, a semiconductor manufacturing device comprises a treatment tank in which treatment of a workpiece is performed using a chemical solution containing nitric acid; a pipe connected to the treatment tank and through which nitric oxide (NO) that is generated by the treatment is recovered from the treatment tank; and a sensor configured to detect and output a physical quantity related to an amount of the NO that is recovered through the pipe.

Hereinafter, embodiments according to the present invention will be described with reference to the drawings. Those embodiments are not intended to limit the present invention. The drawings are schematic or conceptual in nature and ratios of respective portions and the like are not necessarily the same as actual values thereof. In the specification and the drawings, elements similar to those having been already described with respect to existing drawings will be denoted by the same reference signs and detailed descriptions will be omitted when appropriate.

### First Embodiment

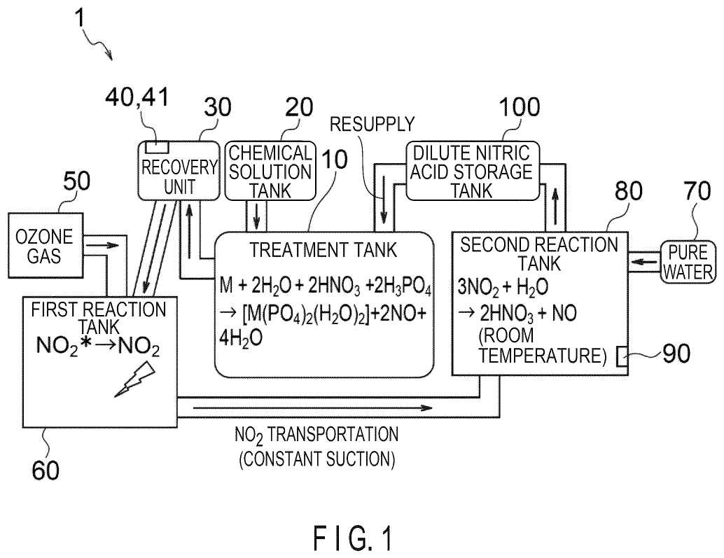

FIG. 1 is a block diagram showing a configuration of a semiconductor manufacturing device 1 according to a first embodiment.

The semiconductor manufacturing device 1 includes a treatment tank 10, a chemical solution tank 20, a recovery unit 30, a detection unit 40, an ozone gas supply unit 50, a first reaction tank 60, a pure water supply unit 70, a second reaction tank 80, a nitric acid concentration meter 90, and a dilute nitric acid storage tank 100.

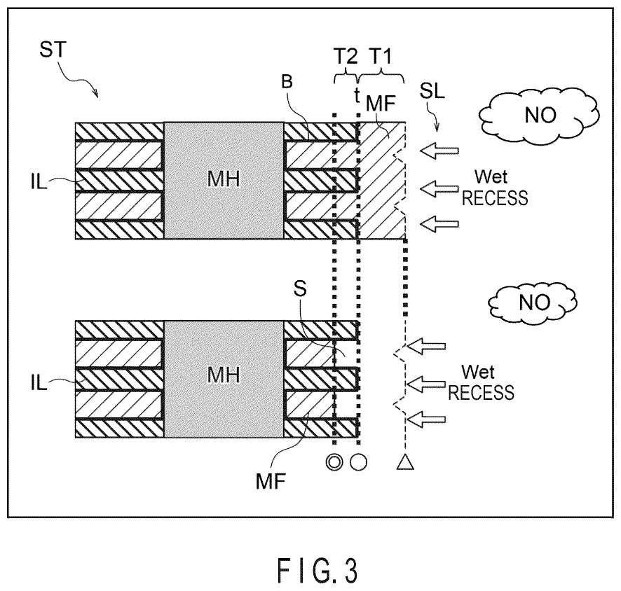

The treatment tank 10 performs treatment of a workpiece using a chemical solution containing nitric acid and phosphoric acid. The chemical solution may further contain acetic acid. The treatment is, for example, an etching treatment. As will be described later with reference to FIG. 3, the workpiece is, for example, a metal film MF. A reaction formula of the etching treatment is represented by Expression 1, where M denotes metal.

$$M + H 2 O + 2 HNO 3 + 2 H 3 PO 4 \to [ M ( P O 4 ) 2 ( H 2 O ) 2 ] + 2 NO + 4 H 2 O \qquad ( Expression 1 )$$

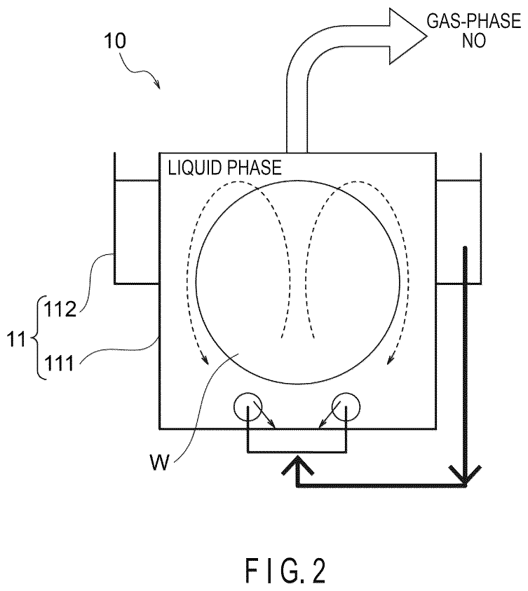

Although not limited thereto, the metal is, for example, tungsten (W). Details of the treatment tank 10 will be described later with reference to FIG. 2.

The chemical solution tank 20 stores the chemical solution and supplies the chemical solution to the treatment tank 10.

The recovery unit 30 recovers NO generated by the treatment from the treatment tank 10. For example, the recovery unit 30 is a gas line (or a gas pipe) provided between the treatment tank 10 and the first reaction tank 60.

The detection unit 40 detects a physical quantity in accordance with an amount of generated NO in the treatment tank 10. A detection result of the detection unit 40 is used to determine a time of treatment by the treatment tank 10. The detection unit 40 according to the first embodiment is a NO concentration meter 41 that detects a concentration of NO in the recovery unit 30 (for example, NO that passes through the gas line).

The NO concentration meter 41 is, for example, an NDIR (Non-Dispersive InfraRed) gas sensor. Detection sensitivity is, for example, in units of ppm.

The ozone gas supply unit 50 supplies ozone gas to the first reaction tank 60. The ozone gas is transported by a gas line provided between the ozone gas supply unit 50 and the first reaction tank 60.

The first reaction tank 60 generates NO2 from the NO recovered by the recovery unit 30. More specifically, the first reaction tank 60 generates nitrogen dioxide (NO2) by causing the NO recovered by the recovery unit 30 to react with ozone (O3). A reaction formula of the generation of NO2 is represented by Expressions 2 to 4, where M denotes a concentration of components that coexist in air.

$$NO + O3 \to {NO2}^{*} \qquad ( Expression 2 )$$

$${NO2}^{*} \to NO 2 + hv \qquad ( Expression 3 )$$

$$NO {2}^{*} + M \to NO 2 + {M}^{*} \qquad ( Expression 4 )$$

From Expression 2, excited species (NO2*) of NO2 is generated and, in Expression 3, chemiluminescence occurs during the reaction of generation of NO2. Note that when chemiluminescence is not utilized, the first reaction tank 60 may generate NO2 by reactions other than the reaction with ozone.

The NO2 generated by the first reaction tank 60 is transported by a gas line provided between the first reaction tank 60 and the second reaction tank 80. The NO2 generated by the first reaction tank 60 is transported to the second reaction tank 80 by constant suction.

The pure water supply unit 70 supplies pure water to the second reaction tank 80. The pure water is transported by a pure water supply line provided between the pure water supply unit 70 and the second reaction tank 80.

The second reaction tank 80 (i.e., the nitric acid regeneration tank) generates nitric acid from the NO2 generated by the first reaction tank 60. More specifically, the second reaction tank 80 generates nitric acid by dissolving the NO2 generated by the first reaction tank 60 in pure water. A reaction formula of the generation of nitric acid at room temperature is represented by Expression 5.

$$3 NO2 + H2O \to 2 HNO 3 + NO \qquad ( Expression 5 )$$

The nitric acid concentration meter 90 detects a concentration of nitric acid in the second reaction tank 80. The nitric acid concentration meter 90 is, for example, a concentration meter using UV light absorption photometry. Detection sensitivity is, for example, in units of ppm.

Note that dilute nitric acid in the second reaction tank 80 is transported to the dilute nitric acid storage tank 100 once nitric acid concentration reaches a predetermined concentration.

The dilute nitric acid storage tank 100 stores the dilute nitric acid transported by the second reaction tank 80. The dilute nitric acid in the dilute nitric acid storage tank 100 is resupplied to the treatment tank 10. Accordingly, the nitric acid concentration in the treatment tank 10 can be adjusted.

FIG. 2 is a cross sectional view of the treatment tank 10 according to the first embodiment.

The treatment tank 10 includes a tank 11. The tank 11 includes an inner tank 111 and an outer tank 112. In addition, circulatory temperature control may be performed in the tank 11 by circulation piping (not illustrated) or the like.

The inner tank 111 stores a chemical solution. First, the chemical solution adjusted so as to attain a desired etching rate is stored in the tank 11. Next, a wafer W is immersed in the chemical solution stored in the inner tank 111. Accordingly, the metal film MF on the wafer W is partially removed by the etching treatment.

The outer tank 112 is provided so as to surround an entire circumference of the inner tank 111 and receives and recovers the chemical solution having overflowed from the inner tank 111.

Note that the treatment tank 10 (or the semiconductor manufacturing device 1) may be either a batch type or a sheet type.

The present disclosure relates to a semiconductor manufacturing method of performing an etching treatment of the metal film MF.

FIG. 3 is a cross sectional view of the metal film MF according to the first embodiment. An upper half of FIG. 3 shows the metal film MF before a width of the metal film MF becomes narrow such as at the start of the etching treatment. A lower half of FIG. 3 shows the metal film MF after the width of the metal film MF has become narrow such as at the end of the etching treatment.

FIG. 3 shows a part of manufacturing steps of a semiconductor device. The semiconductor device is, for example, a three-dimensional memory.

First, a stacked body ST in which an insulating layer IL and a sacrificial layer are alternately stacked on top of the wafer W (not illustrated) is formed and a memory hole MH that penetrates the stacked body ST is formed. Next, a NAND string is formed inside the memory hole MH and the sacrificial layer is removed from a slit SL. Next, as shown in the upper half of FIG. 3, a block film B that covers a bottom surface and a side surface of a space S (or a gap) from which the sacrificial layer has been removed and a conductive layer (i.e., the metal film MF) for embedding the space S are formed. In the example shown in the upper half of FIG. 3, the metal film MF is connected on an inner side surface of the slit SL. This leads to a short-circuit between word lines. In consideration thereof, as shown in the lower half of FIG. 3, a part of the metal film MF is removed from the side of the slit SL. In other words, the metal film MF is recessed such that an end surface of the metal film MF becomes positioned inside the space S. The partial removal of the metal film MF is performed by, for example, a wet etching treatment. Gas-phase NO is generated by the wet etching treatment.

A period T1 represents an etching treatment period of the metal film MF from the start of the etching treatment to a timing t at which an end surface of the metal film MF enters the space S (i.e., the width of the metal film MF becomes narrow).

A period T2 represents the etching treatment period of the metal film MF after the timing t.

A surface area of the metal film MF during the period T2 is smaller than a surface area of the metal film MF during the period T1. Therefore, an amount of generated NO during the period T2 is smaller than an amount of generated NO during the period T1. Accordingly, the timing t can be specified from a change over time of the amount of generated NO.

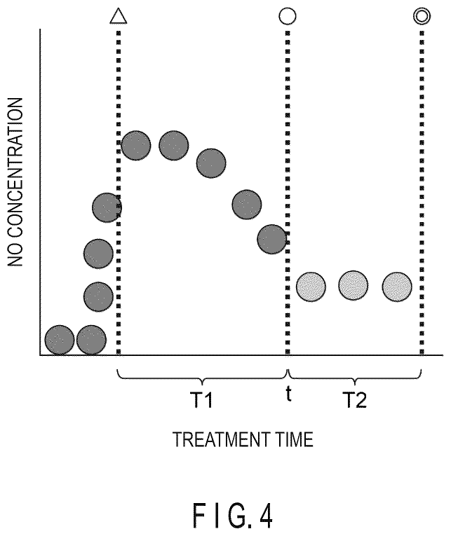

FIG. 4 is a graph showing a relationship between NO concentration and treatment time according to the first embodiment. The axis of ordinate indicates NO concentration. The NO concentration is a detection result of the NO concentration meter 41. The axis of abscissa indicates treatment time.

First, NO concentration rapidly rises with the passage of time from a low value. This is because a reaction of the etching treatment begins and NO that is a reaction by-product starts to be created.

Next, in an initial stage of the period T1, NO concentration is approximately constant with respect to the passage of time. Subsequently, NO concentration gradually drops with the passage of time. This is because, for example, there is a difference in progress of etching treatment between an upper layer portion and a lower layer portion of the stacked body ST and layers in which the width of the metal film MF becomes narrow gradually increases. As described with reference to FIG. 3, when the width of the metal film MF becomes narrow, the amount of generated NO decreases.

Next, during the period T2, NO concentration is approximately constant with respect to the passage of time. This is because the etching treatment proceeds in a state where the width of the metal film MF has become narrow in approximately all layers.

Therefore, NO concentration gradually drops with the passage of time during the period T1 and becomes approximately constant after the timing t being a boundary between the period T1 and the period T2.

The present disclosure relates to an observation with the passage of time of an etching amount (hereinafter, referred to as an amount of recess) during the period T2 in FIG. 3.

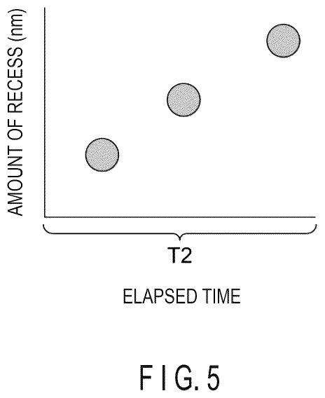

FIG. 5 is a graph showing a relationship between the amount of recess and elapsed time according to the first embodiment. The axis of ordinate indicates the amount of recess (nm) of the metal film MF. The axis of abscissa indicates the period T2 or, in other words, an elapsed time from the timing t.

In the example shown in FIG. 5, the amount of recess has an approximately proportional relationship with the elapsed time from the timing t. By drawing a calibration curve through data points shown in FIG. 5, the relationship between the amount of recess and the elapsed time from the timing t can be defined. Accordingly, the end of the etching treatment can be specified from the elapsed time using the calibration curve.

When the calibration curve differs for each structure of the wafer W, a calibration curve is created for each structure of the wafer W. A target amount of recess can be obtained by stopping the etching treatment after an elapsed time at which the target amount of recess is reached. After the passage of time at which the target amount of recess is reached, for example, the wafer W is pulled out from the treatment tank 10 and cleaned.

As described above, according to the first embodiment, the recovery unit 30 recovers NO generated by treatment from the treatment tank 10. The detection unit 40 detects a physical quantity in accordance with an amount of generated NO in the treatment tank 10. The detection unit 40 is the NO concentration meter 41 that detects a concentration of NO in the recovery unit 30. A detection result of the detection unit 40 (for example, the NO concentration meter 41) is used to determine a time of treatment by the treatment tank 10. In other words, the treatment tank 10 performs the treatment during a time based on the detection result of the detection unit 40 (for example, the NO concentration meter 41). Accordingly, the end of the etching treatment can be detected from the NO concentration. As a result, NO being a reaction by-product can be recovered and utilized to detect the end of etching treatment.

In addition, as shown in FIGS. 4 and 5, a time of treatment by the treatment tank 10 is determined according to a value of a detection result of the detection unit 40 and a sample actual measured value of the amount of recess. Therefore, the end of etching treatment in accordance with a change in the amount of generated NO in the treatment tank 10 as observed by the detection unit 40 can be detected.

A deviation of the amount of recess from a target amount of recess may arise due to, for example, external factors such as a period of exposure to atmosphere after film formation. However, by recovering and utilizing NO that is a reaction by-product, the amount of recess by the etching treatment can be more readily matched with the target amount of recess.

In addition, in the first embodiment, the first reaction tank 60 generates NO2 from the NO recovered by the recovery unit 30. The second reaction tank 80 generates nitric acid from the NO2 generated in the first reaction tank 60. The nitric acid generated by the second reaction tank 80 is used as a chemical solution and supplied to the treatment tank 10. Accordingly, nitric acid can be regenerated using NO that is a reaction by-product. As a result, an amount of use of the chemical solution can be reduced.

Furthermore, a shape of the metal film MF that is a workpiece is not limited to the shape shown in FIG. 3. A shape in which an area of a surface that comes into contact with the chemical solution changes according to progress of the etching treatment is preferable.

### Second Embodiment

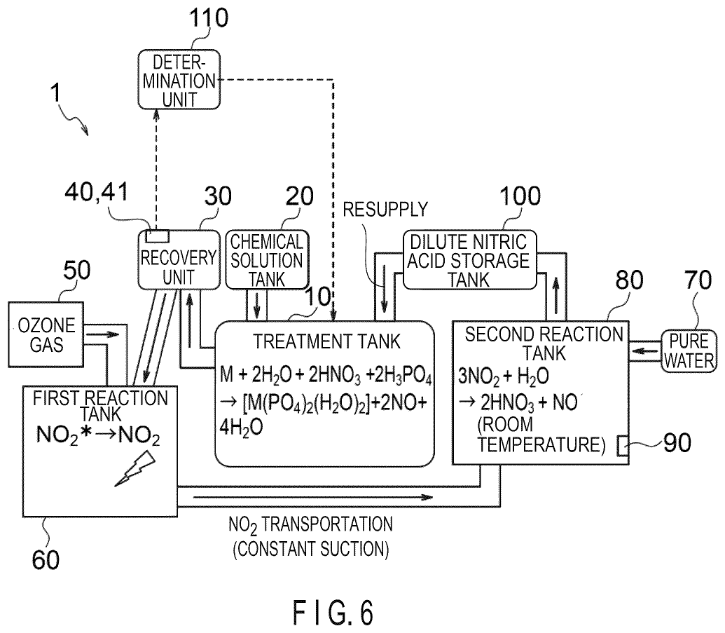

FIG. 6 is a diagram showing a configuration of the semiconductor manufacturing device 1 according to a second embodiment. The second embodiment differs from the first embodiment in that a determination unit 110 is provided.

The semiconductor manufacturing device 1 according to the second embodiment further includes the determination unit 110. The determination unit 110 determines a time of treatment by the treatment tank 10 based on a detection result of the detection unit 40 (for example, the NO concentration meter 41). For example, the determination unit 110 generates the calibration curve described with reference to FIG. 5 and determines a time of treatment according to an input of an amount of recess by a user. Accordingly, the end of the etching treatment can be automatically determined. For example, the determination unit 110 includes a processor such as a CPU (Central Processing Unit).

The determination unit 110 may be provided as in the second embodiment. The semiconductor manufacturing device 1 according to the second embodiment is capable of producing a similar effect to the first embodiment.

### Third Embodiment

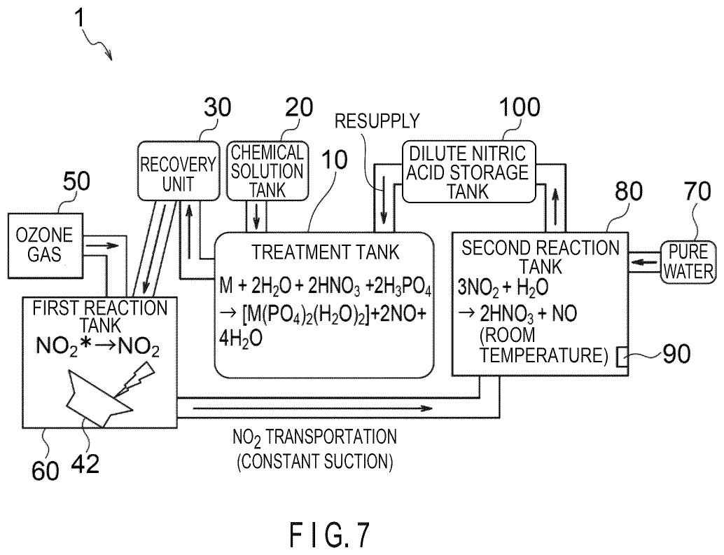

FIG. 7 is a block diagram showing a configuration of the semiconductor manufacturing device 1 according to a third embodiment.

The third embodiment differs from the first embodiment in that emission intensity in the first reaction tank 60 is used to determine an etching treatment time.

The semiconductor manufacturing device 1 according to the third embodiment further includes an emission intensity meter 42. The detection unit 40 according to the third embodiment is the emission intensity meter 42 that detects an emission intensity in the reaction of generation of NO2 in the first reaction tank 60. In this case, the NO concentration meter 41 need not be provided.

The emission intensity meter 42 is a sensor according to a chemiluminescence system based on a standard described in, for example, JIS B 7953 “Continuous analyzers for oxides of nitrogen in ambient air”.

As described with reference to Expression 3, chemiluminescence occurs during the reaction of generation of NO2. The larger the amount of generated NO in the treatment tank 10, the greater the emission intensity in the first reaction tank 60.

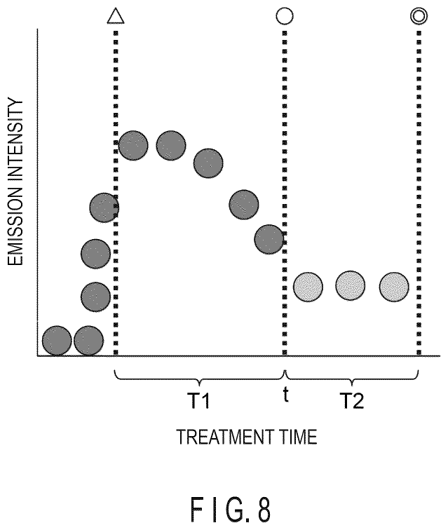

FIG. 8 is a graph showing a relationship between emission intensity and treatment time according to the third embodiment. The axis of ordinate indicates emission intensity. The emission intensity is a detection result of the emission intensity meter 42. The axis of abscissa indicates treatment time.

As shown in FIG. 8, the emission intensity with respect to treatment time exhibits similar behavior to the behavior of NO concentration with respect to treatment time shown in FIG. 4. Therefore, in a similar manner to the first embodiment, NO being a reaction by-product can be recovered and utilized to detect the end of etching treatment. As a result, the detection of the end of etching treatment can also be performed based on emission intensity of NO2 excited species that is created by a reaction between recovered NO and ozone.

As in the third embodiment, the emission intensity in the first reaction tank 60 may be used to determine an etching treatment time. The semiconductor manufacturing device 1 according to the third embodiment is capable of producing a similar effect to the first embodiment. In addition, the second embodiment may be combined with the semiconductor device according to the third embodiment.

### Fourth Embodiment

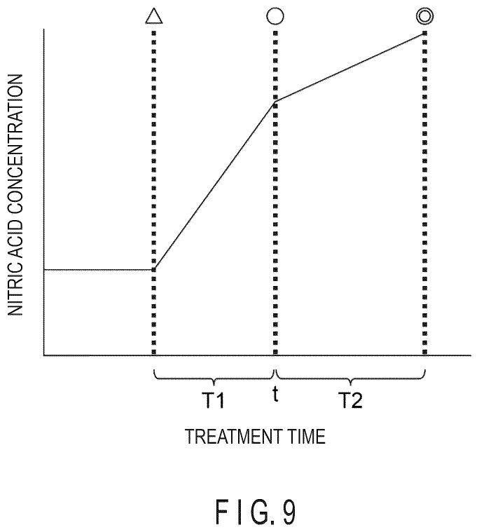

FIG. 9 is a graph showing a relationship between nitric acid concentration and treatment time according to a fourth embodiment. The axis of ordinate indicates nitric acid concentration. The nitric acid concentration is a detection result of a nitric acid concentration meter 43. The axis of abscissa indicates treatment time.

The fourth embodiment differs from the first embodiment in that a rate of a regeneration amount of nitric acid in the second reaction tank 80 is used to determine an etching treatment time.

The detection unit 40 according to the fourth embodiment is the nitric acid concentration meter 43 that detects a concentration of nitric acid in the second reaction tank 80. The nitric acid concentration meter 43 is, for example, the nitric acid concentration meter 90 shown in FIG. 1. In this case, the NO concentration meter 41 need not be provided.

First, the nitric acid concentration is a constant value until reaction of the etching treatment starts.

Next, during the period T1, the nitric acid concentration rises. This is because a reaction of the etching treatment begins and NO that is a reaction by-product starts to be created.

Next, during the period T2, the nitric acid concentration continues to rise. Note that a rate of rise of the nitric acid concentration in the period T2 is lower than a rate of rise of the nitric acid concentration in the period T1. This is because the width of the metal film MF becomes narrow and the amount of generated NO decreases.

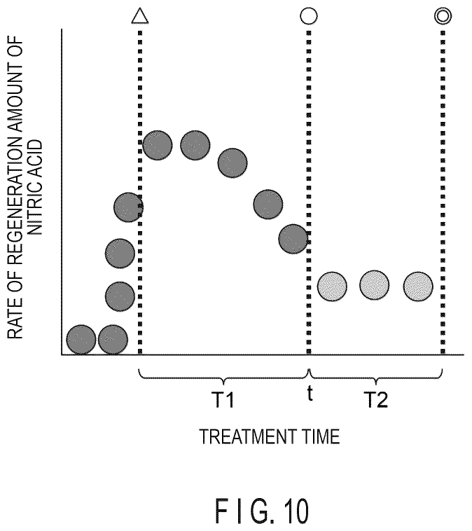

FIG. 10 is a graph showing a relationship between a rate of a regeneration amount of nitric acid and treatment time according to the fourth embodiment. The axis of ordinate indicates a rate of a regeneration amount of nitric acid. The rate of a regeneration amount of nitric acid is calculated from a detection result of the nitric acid concentration meter shown in FIG. 9. The axis of abscissa indicates treatment time.

As shown in FIG. 10, the rate of a regeneration amount of nitric acid with respect to treatment time exhibits similar behavior to the behavior of NO concentration with respect to treatment time shown in FIG. 4. Therefore, in a similar manner to the first embodiment, NO being a reaction by-product can be recovered and utilized to detect the end of etching treatment. As a result, the detection of the end of etching treatment can also be performed based on an amount of regenerated HNO3 due to dissolution in water of NO2 in the second reaction tank 80 (i.e., the nitric acid regeneration tank).

As in the fourth embodiment, the rate of a regeneration amount of nitric acid in the second reaction tank 80 may be used to determine an etching treatment time. The semiconductor manufacturing device 1 according to the fourth embodiment is capable of producing a similar effect to the first embodiment. In addition, the second embodiment may be combined with the semiconductor device according to the fourth embodiment.

At least a part of a data processing method in the semiconductor manufacturing device 1 and the method of manufacturing a semiconductor device according to the above-described embodiments can be performed by hardware and/or software. For example, a program that realizes at least a part of functions of the data processing method may be stored in a non-transitory computer readable recording medium such as a flexible disk or a CD-ROM and the program may be read and executed by a computer. The recording medium is not limited to a removable recording medium such as a magnetic disk or an optical disk and may be a fixed recording medium such as a hard disk device or a memory. In addition, a program that realizes at least a part of functions of the data processing method may be distributed via a communication line (including wireless communication) such as the Internet. Furthermore, the program may be distributed via a wireless line such as the Internet or a wired line or distributed by being stored in a recording medium in an encrypted state, a modulated state, or a compressed state.

While certain embodiments have been described, these embodiments have been presented by way of example only, and are not intended to limit the scope of the inventions. Indeed, the devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor manufacturing device, comprising:
a treatment tank in which treatment of a workpiece is performed using a chemical solution containing nitric acid;
a pipe connected to the treatment tank and through which nitric oxide (NO) that is generated by the treatment is recovered from the treatment tank; and
a sensor configured to detect and output a physical quantity related to an amount of the NO that is recovered through the pipe.

2. The semiconductor manufacturing device according to claim 1, wherein the sensor is an NO concentration meter attached to the pipe and configured to detect and output a concentration of the NO that is recovered through the pipe.

3. The semiconductor manufacturing device according to claim 1, further comprising:
a first reaction tank connected to the pipe and in which the recovered NO reacts with ozone to generate nitrogen dioxide (NO2); and
a second reaction tank connected to the first reaction tank and in which the NO2 generated in the first reaction tank reacts with pure water to generate nitric acid.

4. The semiconductor manufacturing device according to claim 3, further comprising:
another pipe through which the nitric acid generated in the second reaction tank is supplied to the treatment tank.

5. The semiconductor manufacturing device according to claim 3, wherein the sensor is an emission intensity meter attached to the first reaction tank and configured to detect and output an intensity of light emitted therein.

6. The semiconductor manufacturing device according to claim 3, further comprising:
a nitric acid concentration meter attached to the second reaction tank and configured to detect and output a concentration of the nitric acid therein.

7. The semiconductor manufacturing device according to claim 3, further comprising:
a storage tank connected between the treatment tank and the second reaction tank and through which the nitric acid generated in the second reaction tank is transferred to the treatment tank.

8. The semiconductor manufacturing device according to claim 1, further comprising:
a processor configured to determine an end of the treatment based on the physical quantity that is output by the sensor.

9. The semiconductor manufacturing device according to claim 8, wherein
the physical quantity is a concentration of the NO that is recovered through the pipe, and
the processor is configured to determine the end of the treatment based on a variation in the concentration of the NO after the treatment has started.

10. The semiconductor manufacturing device according to claim 1, wherein an area of a surface of the workpiece that comes into contact with the chemical solution changes according to a progress of the treatment in the treatment tank.

11. A semiconductor manufacturing device, comprising:
a treatment tank in which treatment of a workpiece is performed using a chemical solution containing nitric acid;
a pipe connected to the treatment tank and through which nitric oxide (NO) that is generated by the treatment is recovered from the treatment tank;
a first reaction tank connected to the pipe and in which the recovered NO reacts with ozone to generate nitrogen dioxide (NO2); and
a second reaction tank connected to the first reaction tank and in which the generated NO2 reacts with pure water to generate nitric acid.

12. The semiconductor manufacturing device according to claim 11, further comprising:
a sensor configured to detect and output a physical quantity related to an amount of the NO that is recovered through the pipe.

13. The semiconductor manufacturing device according to claim 12, wherein the sensor is an NO concentration meter attached to the pipe and configured to detect and output a concentration of the NO that is recovered through the pipe.

14. The semiconductor manufacturing device according to claim 12, wherein the sensor is an emission intensity meter attached to the first reaction tank and configured to detect and output an intensity of light emitted therein.

15. The semiconductor manufacturing device according to claim 12, wherein the sensor is a nitric acid concentration meter attached to the second reaction tank and configured to detect and output a concentration of the nitric acid therein.

16. A method of manufacturing a semiconductor device, the method comprising:
beginning treatment of a workpiece using a chemical solution containing acid in a treatment tank;
recovering nitric oxide (NO) generated by the treatment from the treatment tank through a pipe;
detecting a physical quantity related to an amount of the NO recovered through the pipe; and
determining an end of the treatment based on the detected physical quantity.

17. The method according to claim 16, wherein the end of the treatment is determined based on an elapsed time after the detected physical quantity falls into a particular range.

18. The method according to claim 16, wherein the physical quantity is a concentration of the NO recovered through the pipe.

19. The method according to claim 16, further comprising:
supplying the NO recovered through the pipe to a first reaction tank to cause the NO to react with ozone in the first reaction tank and thereby generate NO2 therein, wherein
the physical quantity is an intensity of light emitted in the first reaction tank.

20. The method according to claim 16, further comprising:
supplying the recovered NO to a first reaction tank to cause the NO to react with ozone in the first reaction tank and thereby generate NO2 therein; and
supplying the generated NO2 to a second reaction tank to cause the NO2 to react with pure water in the second reaction tank and thereby generate nitric acid therein, wherein
the physical quantity includes a concentration of the nitric acid generated in the second reaction tank, and
the end of the treatment is determined further based on a rate of a regeneration amount of the nitric acid.
